(19) United States
(12) Patent Application Publication
(10) Pub. No.: US 2015/0249068 A1
(43) Pub. Date: Sep. 3, 2015

(54) CHIP PACKAGE STRUCTURE

(71) Applicant: Silergy Semiconductor Technology (Hangzhou) LTD, Hangzhou (CN)

(72) Inventor: Jiaming Ye, Hangzhou (CN)

(21) Appl. No.: 14/613,593

(22) Filed: Feb. 4, 2015

(30) Foreign Application Priority Data
Feb. 28, 2014 (CN) 201420090766.9

(51) Int. Cl. H01L 25/065; H01L 23/48; H01L 23/00

(52) U.S. Cl. CPC H01L 25/0657; H01L 24/49; H01L 24/17; H01L 24/73; H01L 23/481; H01L 2225/06513; H01L 2225/0651; H01L 2225/06506; H01L 2225/06541; H01L 2224/73257; H01L 2224/48106; H01L 2224/48227; H01L 2224/16113; H01L 2224/16227; H01L 2224/023; H01L 2225/06555; H01L 2924/12

(57) ABSTRACT

In one embodiment, a chip package structure can include: (i) a substrate; (ii) a top chip including a plurality of vias arranged through the top chip to form electrical connections between an active surface of the top chip and a back surface of the top chip; (iii) a redistribution layer arranged on the back surface of the top chip; and (iv) a plurality of wire bonds that form electrical connections between the substrate and electrodes on the redistribution layer on the back surface of the top chip.

### RELATED APPLICATIONS

This application claims the benefit of Chinese Patent Application No. 201420090766.9, filed on Feb. 28, 2014, which is incorporated herein by reference in its entirety.

### FIELD OF THE INVENTION

The present invention generally relates to the field of semiconductor packaging, and more specifically relates to a chip package structure.

### BACKGROUND

In many package structures, the front surface of a semiconductor chip can be configured as an active surface with electrodes, and the back surface thereof can be configured as a package without any electrodes. A flip chip may be formed by connecting the front surface of a chip to a substrate via conductive bumps. Such flip packaging is widely used due to advantages of relatively good electrical and thermal performance, as well overall minimization.

### SUMMARY

In one embodiment, a chip package structure can include: (i) a substrate; (ii) a top chip including a plurality of vias arranged through the top chip to form electrical connections between an active surface of the top chip and a back surface of the top chip; (iii) a redistribution layer arranged on the back surface of the top chip; and (iv) a plurality of wire bonds that form electrical connections between the substrate and electrodes on the redistribution layer on the back surface of the top chip.

### BRIEF DESCRIPTION OF THE DRAWINGS

FIG. 1 is a cross-sectional diagram of a first example chip package structure, in accordance with embodiments of the present invention.

FIG. 2 is a cross-sectional diagram of a second example chip package structure, in accordance with embodiments of the present invention.

FIG. 3 is a cross-sectional diagram of a third example chip package structure, in accordance with embodiments of the present invention.

FIG. 4 is a cross-sectional diagram of a fourth example chip package structure, in accordance with embodiments of the present invention.

FIG. 5 is a schematic diagram of an example synchronous switching voltage regulator, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

An active surface of a chip may have a relatively high number of electrodes (e.g., connections external to the chip) when the chip is highly integrated. Such electrodes may be connected to the package substrate through conductive bumps, the number of which may be limited when the chip is flip packaged because of limited area of the active surface. As a result, some electrodes may not be lead out to allow for external connection (e.g., external to the package). In addition, it may be difficult to lead some electrodes from inside the device to the active surface of the chip due to the special position or orientation of some devices (e.g., a power device) in the chip.

In particular embodiments, a chip package structure can accommodate appropriate arrangement of conductive bumps with relatively high integration and relatively small volume, while leading out suitable electrodes. For example, devices that are positioned with electrodes at a back surface of the chip can be accommodated in certain embodiments. This can allow for improved integration and chip packaging for a variety of semiconductors, such as power chips and/or devices.

In one embodiment, a chip package structure can include: (i) a substrate; (ii) a top chip including a plurality of vias arranged through the top chip to form electrical connections between an active surface of the top chip and a back surface of the top chip; (iii) a redistribution layer arranged on the back surface of the top chip; and (iv) a plurality of wire bonds that form electrical connections between the substrate and electrodes on the redistribution layer on the back surface of the top chip.

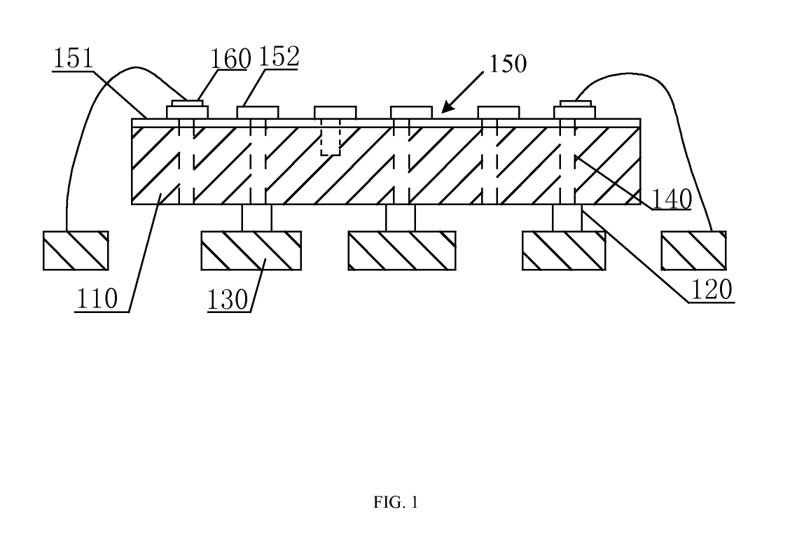

Referring now to FIG. 1, shown is a cross-sectional diagram of a first example chip package structure, in accordance with embodiments of the present invention. In this particular example, top chip 110 may have an active surface that is electrically connected to substrate 130 through conductive bumps 120. Vias (e.g., through-silicon vias [TSVs]) 140 arranged in/through the top chip can be used to connect electrodes on the active surface (e.g., bottom surface in the diagram because the chip is flipped) or active region of top chip 110 to the back surface (e.g., top surface in the diagram because the chip is flipped).

Also, the back surface of top chip 110 can be configured with redistribution layer 150. Redistribution layer 150 can include insulating layer 151 and pattern conductive layer 152. For example, insulating layer 151 may cover the back surface of top chip 110, and pattern conductive layer 152 can be on insulating layer 151 and electrically connected to corresponding vias 140. In addition, pads 160 can be arranged on redistribution layer 150, and may be connected via bonding wire to substrate 130.

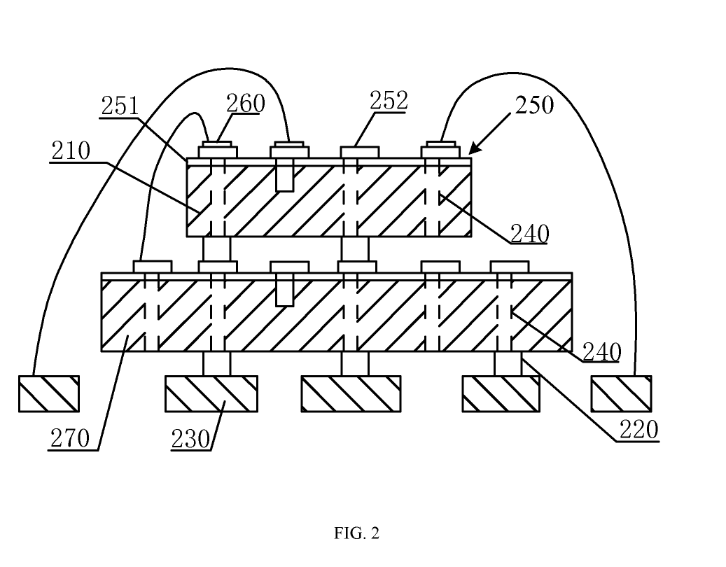

Referring now to FIG. 2, shown is a cross-sectional diagram of a second example chip package structure, in accordance with embodiments of the present invention. In this particular example, top chip 210 and bottom chip 270 are arranged in a stacked configuration. Bottom chip 270 can also include vias 240 used to lead out the electrodes (e.g., for external connection to chip 270) on the active surface or active region of bottom chip 270 for connection to the back surface of bottom chip 270. Both of top chip 210 and bottom chip 270 can be flipped in this arrangement, so the active surface may be the bottom side as shown in the diagram.

Redistribution layer 250 can include insulating layer 251 and pattern conductive layer 252, and may be arranged on the back surface of bottom chip 270. The active surface of the bottom chip can be electrically connected to substrate 230 through conductive bumps 220. Also, the active surface of top chip 210 can be electrically connected to redistribution layer 250 on the back surface of bottom chip 270 through conductive bumps 220. Redistribution layer 250 on the back surface of top chip 210 can lead out electrodes that may be connected to bottom chip 270 through lead bonding. Pads 260 can be arranged on redistribution layer 250 of top chip 210 for lead bonding to bottom chip 270. Thus, wire bonding can be utilized to connect electrodes of top chip 210 to those of bottom chip 270 and/or to form connections between top chip 210 and substrate 230 (e.g., for external connections to the package).

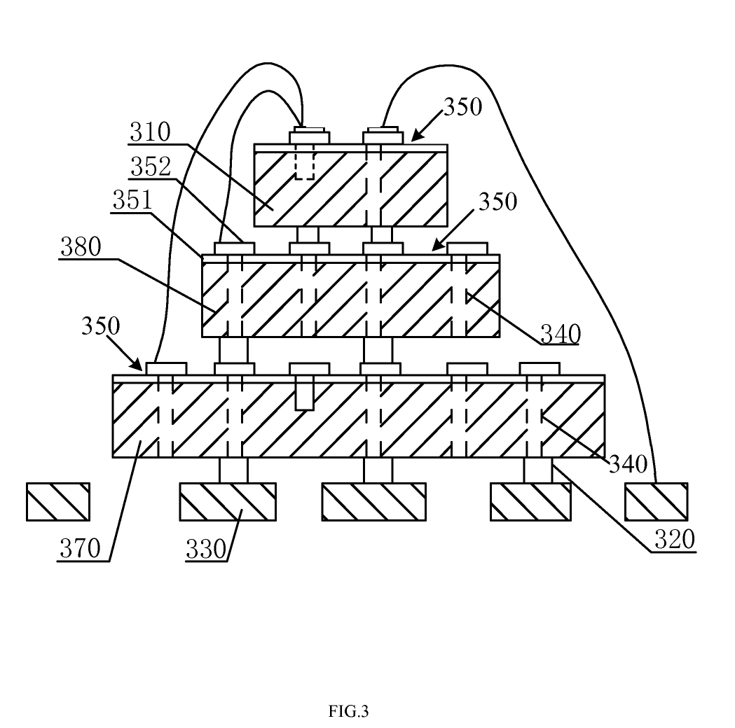

Referring now to FIG. 3, shown is a cross-sectional diagram of a third example chip package structure, in accordance with embodiments of the present invention. In this particular example, “medium” chip 380 can be arranged between top chip 310 and bottom chip 370. While one medium chip shown in this example, any suitable number of such medium chips can be included in particular embodiments. Medium chip 380 can include vias 340 for leading electrodes on the active surface or active region of medium chip 380 to the back surface of medium chip 380.

Redistribution layer 350 (e.g., including insulating layer 351 and pattern conductive layer 352) can be arranged on the back surface of medium chip 380. The active surface of top chip 310 can be electrically connected to redistribution layer 350 on the back surface of medium layer 380 through conductive bumps 320. The active surface of medium chip 380 can be electrically connected to redistribution layer 350 on the back surface of bottom chip 370 through conductive bumps 320. Redistribution layer 350 on the back surface of top chip 310 can lead electrodes to redistribution layer 350 on the back surface of bottom chip 370 and/or to medium chip 380.

Lead bonding can be to bottom chip 370 and/or medium chip 380. In this particular example, lead/wire bonding to redistribution layers 350 on the back surfaces of bottom chip 370 and medium chip 380 from a pad of top chip 310 is shown. In addition, the active surface of bottom chip 370 can be electrically connected to substrate 330 through conductive bumps 320. Also as shown in the example of FIG. 3, top chip 310 may have a width that is less than that of medium chip 380, and medium chip 380 may have a width that is less than that of bottom chip 370.

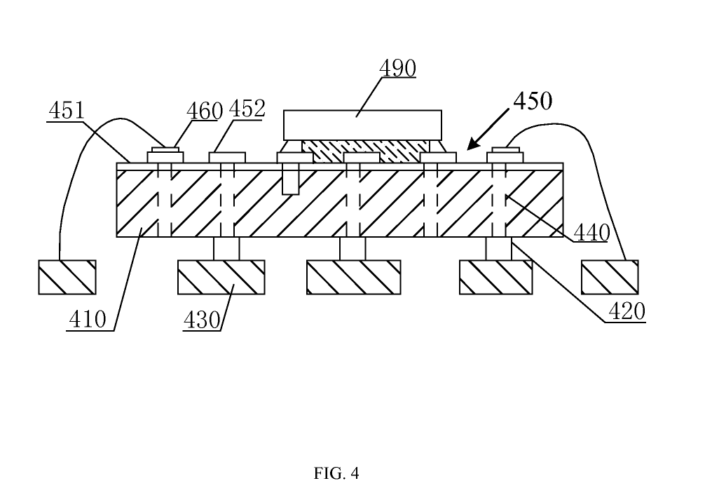

Referring now to FIG. 4, shown is a cross-sectional diagram of a fourth example chip package structure, in accordance with embodiments of the present invention. In this particular example, passive component layer 490 can be arranged on the back surface of top chip 410. Top chip 410 can include vias 440 inside/through, and may be electrically connected to redistribution layer 450 (e.g., including insulating layer 451 and pattern conductive layer 452). Top chip 410 can be electrically connected to substrate 430 through conductive bumps 420.

Pads 460 arranged on redistribution layer 450 can be utilised for wire bonding to substrate 430. Passive component layer 490 can be connected with the back surface of top chip 410, and a non-conductive material can be filled between passive component layer 490 and the back surface of top chip 410. Passive component layer 490 can include any suitable passive component (e.g., an inductor, a capacitor, a resistor, etc.), such as in a switching voltage regulator or light-emitting diode (LED) driver circuit.

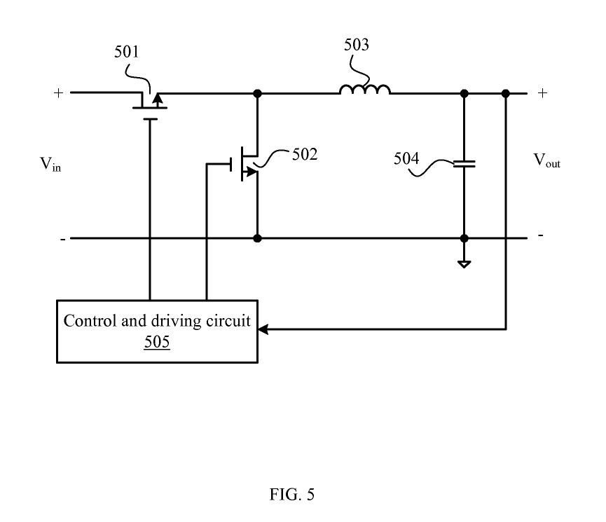

Referring now to FIG. 5, shown is a schematic diagram of an example switching voltage regulator. A switching voltage regulator is just one example of the circuitry that can be included in the packaging structures described herein. In this example, power transistor 501, power transistor 502, inductor 503, and capacitor 504 can form a synchronous buck power stage circuit. In other cases, other types of power stage or converter circuits (e.g., flyback, SEPIC, boost, buck-boost, etc.) can be formed. Control and driving circuit 505 (e.g., including a pulse-width modulation [PWM] controller) can receive an output signal of the power stage circuit, to form a closed-loop feedback control loop to control the switching state of power transistors 501 and 502. In this way, the output signal of the power stage circuit can be controlled to be substantially constant.

The packaging structure described herein can be employed for this type of power circuitry. For example, power transistors 501 and 502 can be integrated into a single chip, and control and driving circuit 505 can be integrated into another chip, and then the two chips can be stacked (see, e.g., FIG. 2) and encapsulated together in the packaging structure. In one example, power transistors 501 and 502 can be integrated in bottom chip 270, control and driving circuit 505 can be integrated in top chip 210. Also, inductor 503 can be integrated in passive component 490. In another example, power transistors 501 and 502, and controlling driving circuit 505 can be integrated in bottom chip 270, and inductor 503 can be integrated in top chip 210.

Of course, other integration or grouping of circuitry into different chips or ICs can be accommodated in particular embodiments. In one example, a multi-chip packaging structure in particular embodiments can include power transistor 501 and power transistor 502 being integrated into a power device chip (e.g., 270), and control and driving circuit 505 being integrated into a control chip (e.g., 210). The power device chip can be placed directly on the substrate, print-circuit board (PCB), or lead frame, such that the area of the power device chip can be as close to the area of the chip carrier or substrate as possible. Since the power device may process a high voltage and/or a high current, the power device chip with a large area can be able to withstand a relatively high voltage and a relatively high current. Also, the power device may have better thermal characteristics for power supply integration.

For the integrated circuit of the switching voltage regulator shown in FIG. 5, if the carrying capacity of power transistor 502 is greater than that of power transistor 501, power transistor 502 may be much larger than power transistor 501. Thus, power transistor 502 (e.g., the synchronous power device) can be integrated in a single synchronous power device chip, and power transistor 501 (e.g., the main power device) as well as control and driving circuit 505 can be integrated in another single mixed chip. The synchronous power device chip (e.g., 270) can be placed on substrate/lead frame or PCB 230 and connected via conductive bumps 220.

In addition, for magnetic components, by adopting the stacked packaging structure, an inductor and associated chips can be packaged in a single packaging structure. Thus, an inductor with relatively large volume and capacitance can be integrated with other chips or devices in the same packaging structure. In this way, the overall system (e.g., a power regulator) can be highly integrated with associated components (e.g., inductors, capacitors, etc.) in a relatively small volume.

The structures of above examples are not independent from each other, and combinations and modifications can be obtained and not limited to above described examples. For example, the passive component layer in the example of FIG. 4 is also applicable to the examples of FIGS. 2 and 3. The conductive holes can be vias (e.g., TSVs) or blind holes, in some cases. For example, the conductive vias may run through the active region of the chip, where the active region refers to an area including active devices (e.g., transistors), and some electrodes (e.g., the signals between control and driving circuit 505 and power transistors 501 and 502) of active devices can be lead out to the back surface of a chip through conductive holes.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A chip package structure, comprising:
a) a substrate;
b) a top chip comprising a plurality of vias arranged through said top chip to form electrical connections between an active surface of said top chip and a back surface of said top chip;
c) a redistribution layer arranged on said back surface of said top chip; and
d) a plurality of wire bonds that form electrical connections between said substrate and electrodes on said redistribution layer on said back surface of said top chip.

2. The chip package structure of claim 1, further comprising a plurality of conductive bumps that form electrical connections between said substrate and said active surface of said top chip.

3. The chip package structure of claim 1, wherein said redistribution layer of said top chip comprises:
a) an insulating layer that covers said back surface of said top chip; and
b) a pattern conductive layer arranged on said insulating layer and that is electrically connected to corresponding of said plurality of vias.

4. The chip package structure of claim 1, wherein said chip package structure further comprises a passive component layer arranged on said top chip and that is electrically connected to said redistribution layer of said top chip.

5. The chip package structure of claim 1, further comprising:
a) a bottom chip located under said top chip, wherein said bottom chip comprises a plurality of vias through said bottom chip to form connections between an active surface of said bottom chip and a back surface of said bottom chip; and
b) a redistribution layer arranged on said back surface of said bottom chip, wherein said active surface of said bottom chip is electrically connected to said substrate through a plurality of conductive bumps.

6. The chip package structure of claim 5, wherein said redistribution layer of said bottom chip comprises:
a) an insulating layer that covers said back surface of said bottom chip; and
b) a pattern conductive layer is arranged on said insulating layer of said bottom chip and that is electrically connected to corresponding of said plurality of vias through said bottom chip.

7. The chip package structure of claim 5, wherein said active surface of said top chip is electrically connected to said redistribution layer on said back surface of said bottom chip through a plurality of conductive bumps.

8. The chip package structure of claim 5, further comprising:
a) a medium chip arranged between said top chip and said bottom chip, wherein said medium chip comprises a plurality of vias through said medium chip to form connections between an active surface of said medium chip and a back surface of said medium chip;
b) a redistribution layer arranged on said back surface of said medium chip; and
c) a plurality of conductive bumps that provide electrical connection between said active surface of said top chip and said redistribution layer on said back surface of said medium layer, and between said active surface of said medium chip and said redistribution layer on said back surface of said bottom chip.

9. The chip package structure of claim 8, further comprising a plurality of wire bonds that connect electrodes from said redistribution layer on said back surface of said top chip to said redistribution layer on said back surface of said bottom chip.

10. The chip package structure of claim 8, further comprising a plurality of wire bonds that connect electrodes from said redistribution layer on said back surface of said top chip to said redistribution layer on said back surface of said medium chip.

11. The chip package structure of claim 8, further comprising a plurality of wire bonds that connect electrodes from said redistribution layer on said back surface of said top chip to said substrate.

12. The chip package structure of claim 8, wherein said redistribution layer of said medium chip comprises:
a) an insulating layer that covers said back surface of said medium chip; and
b) a pattern conductive layer is arranged on said insulating layer of said medium chip and that is electrically connected to corresponding of said plurality of vias through said medium chip.
